(19) United States
(12) Patent Application Publication
(10) Pub. No.: US 2025/0164897 A1
(43) Pub. Date: May 22, 2025

(54) STAGE AND ERROR COMPENSATION SYSTEM USING THE SAME

(71) Applicant: Samsung Display Co., LTD., Yongin-si (KR)

(72) Inventors: Jungwoong Byun, Yongin-si (KR); CHEONG-WAN MIN, Yongin-si (KR); JAIHYUK CHOI, Yongin-si (KR); MYUNGSOO HUH, Yongin-si (KR)

(73) Assignee: Samsung Display Co., LTD., Yongin-si (KR)

(21) Appl. No.: 18/949,124

(22) Filed: Nov. 15, 2024

(30) Foreign Application Priority Data
Nov. 20, 2023 (KR) 10-2023-0160318

(51) Int. Cl. G03F 7/00; B41J 11/06; B41J 11/14; B65G 54/02; F16C 32/06; F16M 11/04; F16M 11/18; H01F 7/08; H01F 27/08; H01F 27/28; H01L 21/687

(52) U.S. Cl. CPC G03F 7/70725; B41J 11/06; B41J 11/14; B65G 54/02; F16M 11/043; F16M 11/18; G03F 7/70758; G03F 7/70775; G03F 7/70816; G03F 7/70875; H01F 7/08; H01F 27/08; H01F 27/28; F16C 32/0603; H01L 21/68785

(57) ABSTRACT

A stage includes a base plate extending in a first direction and a second direction intersecting the first direction, a moving frame disposed on the base plate and movable in the first direction or in a direction opposite to the first direction, and an error compensation portion disposed between the base plate and the moving frame and including a guide rail extending in the first direction and an electromagnet portion disposed on the guide rail and covering at least a portion of the guide rail.

### CROSS-REFERENCE TO RELATED APPLICATION(S)

This application claims priority to Korean Patent Application No. 10-2023-0160318 under 35 U.S.C. § 119, filed on Nov. 20, 2023, in the Korean Intellectual Property Office (KIPO), the entire contents of which are incorporated herein by reference.

### BACKGROUND

### 1. Technical Field

Embodiments relate to a stage. More specifically, embodiments relate to a stage and an error compensation system using the stage.

### 2. Description of the Related Art

A stage is a device that supports and precisely transfers a substrate, a wafer, or the like in a manufacturing process of a display device, a semiconductor, or the like. The stage may include a mover that supports the substrate, the wafer, or the like and linearly moves, and a guide for the linear motion of the mover. While the mover performs the linear motion, a translational motion error or a rotational motion error may occur in x-axis, y-axis, and z-axis directions.

### SUMMARY

Embodiments provide a stage with improved reliability.

Embodiments provide an error compensation system using the stage.

However, embodiments are not limited to those set forth herein. The above and other embodiments will become more apparent to one of ordinary skill in the art to which the disclosure pertains by referencing the detailed description of the disclosure given below.

A stage according to an embodiment includes a base plate extending in a first direction and a second direction intersecting the first direction, a moving frame disposed on the base plate and movable in the first direction or in a direction opposite to the first direction, and an error compensation portion disposed between the base plate and the moving frame and including a guide rail extending in the first direction and an electromagnet portion disposed on the guide rail and covering at least a portion of the guide rail.

In an embodiment, the electromagnet portion may include a coil disposed on at least one surface of the guide rail and a yoke covering the coil.

In an embodiment, the coil may include a first coil and a second coil adjacent to the first coil in the first direction and wound in a direction opposite to a direction in which the first coil is wound.

In an embodiment, the yoke may include a cover portion covering the coil and an iron core portion protruding in a direction toward the guide rail.

In an embodiment, the coil may be wound around the iron core portion.

In an embodiment, the electromagnet portion may further include a cooling line passing through the yoke.

In an embodiment, the guide rail and the electromagnet portion may be spaced apart from each other.

In an embodiment, the stage may further include an air bearing disposed on at least one surface of the moving frame.

In an embodiment, the stage may further include a linear motor fixed to the moving frame and movable in the first direction or in the direction opposite to the first direction. The moving frame may be movable by the linear motor.

In an embodiment, the guide rail may be fixed to the base plate, and the electromagnet portion may be fixed to the moving frame.

In an embodiment, the error compensation portion may be disposed on an upper surface of the base plate.

In an embodiment, the error compensation portion may be disposed on a side surface of the base plate.

An error compensation system according to an embodiment includes a stage. The stage includes a base plate extending in a first direction and a second direction intersecting the first direction, a moving frame disposed on the base plate and movable in the first direction or in a direction opposite to the first direction, and an error compensation portion disposed between the base plate and the moving frame and including a guide rail extending in the first direction and an electromagnet portion disposed on the guide rail and covering at least a portion of the guide rail.

In an embodiment, the electromagnet portion may include a coil disposed on at least one surface of the guide rail and to which a current is applied, a yoke covering the coil, and a cooling line passing through the yoke.

In an embodiment, the coil may include a first coil wound in a direction and a second coil adjacent to the first coil in the first direction and wound in a direction opposite to the direction.

In an embodiment, the yoke may include a cover portion covering the coil and an iron core portion protruding in a direction toward the guide rail and around which the coil is wound.

In an embodiment, a motion error of the moving frame may be compensated by controlling the current applied to the coil.

In an embodiment, an attractive force may be generated between the guide rail and the electromagnet portion by the current applied to the coil, and a magnitude of the attractive force may be adjusted by controlling a magnitude of the current applied to the coil.

In an embodiment, heat generated from the coil may be released by flowing coolant into the cooling line.

In an embodiment, the guide rail and the electromagnet portion may be spaced apart from each other.

In an error compensation system according to embodiments, the error compensation system may include a stage including an error compensation portion. The error compensation portion may include a guide rail extending in a direction and an electromagnet portion that generates a magnetic flux. In case that a linear motion error occurs in the stage, the error may be compensated by controlling a current applied to a coil of the electromagnet portion. For example, in case that heat is generated from the coil of the electromagnet portion due to the current, the generated heat may be released by flowing coolant into a cooling line of the electromagnet portion. Therefore, since the linear motion error with respect to multi-axis may be precisely compensated, an ultra-precision stage with improved reliability may be implemented.

### BRIEF DESCRIPTION OF THE DRAWINGS

FIG. 1 is a schematic plan view illustrating a stage according to an embodiment.

FIG. 2 is a schematic cross-sectional view taken along line I-I′ of FIG. 1.

FIG. 3 is a schematic perspective view illustrating an error compensation portion included in the stage of FIG. 1.

FIG. 4 is a schematic front view illustrating the error compensation portion of FIG. 3.

FIG. 5 is a schematic perspective view illustrating an electromagnet portion included in the error compensation portion of FIG. 3.

FIG. 6 is a schematic cross-sectional view taken along line II-II′ of FIG. 3.

FIG. 7 is a schematic perspective view taken along line III-III′ of FIG. 3.

FIG. 8 is a perspective view taken along line IV-IV′ of FIG. 4.

FIG. 9 is a schematic view illustrating an error compensation system according to an embodiment.

FIG. 10 is a schematic plan view illustrating a stage according to another embodiment.

FIG. 11 is a schematic cross-sectional view taken along line V-V′ of FIG. 10.

FIG. 12 is a schematic view illustrating an error compensation system according to another embodiment.

FIG. 13 is a schematic plan view illustrating a stage according to still another embodiment.

FIG. 14 is a schematic cross-sectional view taken along line VI-VI′ of FIG. 13.

FIG. 15 is a schematic view illustrating an error compensation system according to still another embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, embodiments will be described in more detail with reference to the accompanying drawings. The same reference numerals are used for the same components in the drawings, and redundant descriptions of the same components will be omitted.

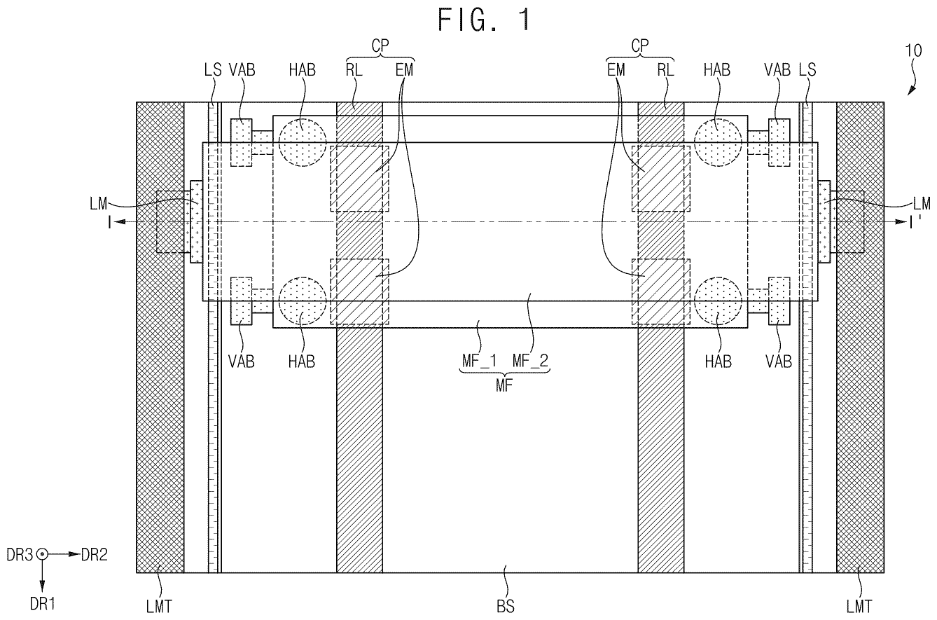

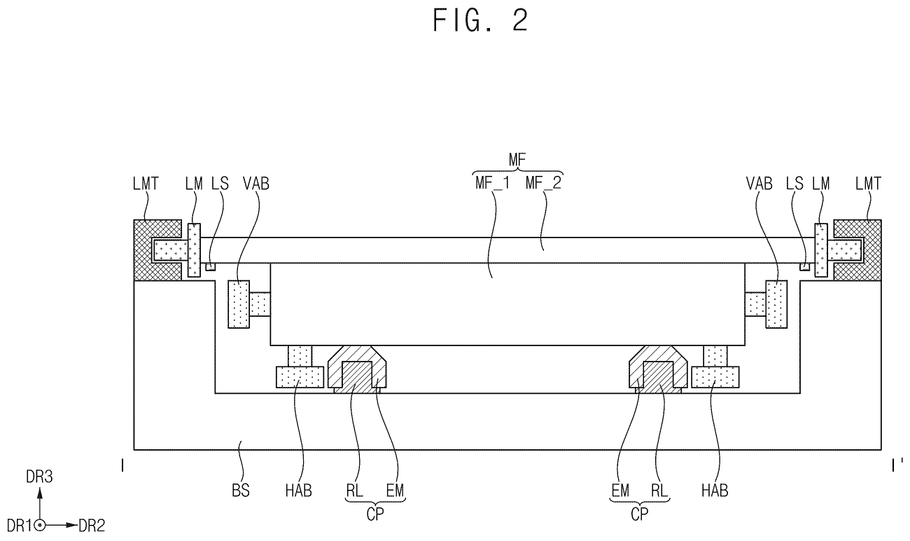

FIG. 1 is a schematic plan view illustrating a stage according to an embodiment. FIG. 2 is a schematic cross-sectional view taken along line I-I′ of FIG. 1.

Referring to FIGS. 1 and 2, a stage 10 may include a base plate BS, a moving frame MF, a linear motor LM, a linear motor track LMT, a linear scale LS, a horizontal air bearing HAB, a vertical air bearing VAB, and an error compensation portion CP.

The stage 10 may be used in a manufacturing process of a display device. For example, the stage 10 may be used in an inkjet process during the manufacturing process of the display device. For another example, the stage 10 may be used in an exposure process during the manufacturing process of the display device. However, embodiments are not limited thereto, and the stage 10 may be used in various processes that require precise control during the manufacturing process of the display device.

The base plate BS may extend in a first direction DR1 and a second direction DR2 intersecting the first direction DR1. For example, the second direction DR2 may be perpendicular to the first direction DR1. The base plate BS may define (or provide) a space recessed from an upper surface to a lower surface of the base plate BS. For example, the base plate BS may include granite.

The moving frame MF may be disposed on the base plate BS. A portion of the moving frame MF may be accommodated in the space of the base plate BS. The moving frame MF may be spaced apart from the base plate BS in a third direction DR3 intersecting each of the first direction DR1 and the second direction DR2. For example, the third direction DR3 may be perpendicular to each of the first direction DR1 and the second direction DR2. The moving frame MF may be movable in the first direction DR1 or in a direction opposite to the first direction DR1.

Although FIGS. 1 and 2 illustrate that the moving frame MF includes a first frame layer MF_1 and a second frame layer MF_2 disposed on the first frame layer MF_1, and each of the first frame layer MF_1 and the second frame layer MF_2 has a rectangular planar shape, embodiments are not limited thereto. For example, although FIGS. 1 and 2 illustrate a length of the first frame layer MF_1 in the first direction DR1 is greater than a length of the second frame layer MF_2 in the first direction DR1, and a length of the first frame layer MF_1 in the second direction DR2 is smaller than a length of the second frame layer MF_2 in the second direction DR2, embodiments are not limited thereto. In another embodiment, the moving frame MF may have a single-layer or multi-layer structure, or may have various shapes or sizes.

The linear motor LM may be disposed on a surface of the moving frame MF. For example, the linear motor LM may be disposed on side surfaces (e.g., opposite side surfaces) of the moving frame MF. The linear motor LM may be fixed (or attached) to the moving frame MF. For example, the linear motor LM may include a coil.

The linear motor track LMT may be disposed on the base plate BS. The linear motor track LMT may extend in the first direction DR1. The linear motor track LMT may define (or provide) a space in which a portion of the linear motor LM may be accommodated. The linear motor track LMT may not be in contact with the linear motor LM. For example, the linear motor track LMT and the linear motor LM may be spaced apart from each other. For example, the linear motor track LMT may include a magnet.

The linear motor LM may be movable in the first direction DR1 or in the direction opposite to the first direction DR1 along the linear motor track LMT. In an embodiment, the linear motor LM and the linear motor track LMT may move the moving frame MF. For example, the linear motor LM and the linear motor track LMT may move the moving frame MF by using an electromagnetic force. The moving frame MF may be movable in the first direction DR1 or in the direction opposite to the first direction DR1 by the linear motor LM and the linear motor track LMT. For example, the moving frame MF may linearly move by the linear motor LM and the linear motor track LMT.

The linear scale LS may be disposed on the base plate BS. For example, the linear scale LS may be disposed below the moving frame MF. The linear scale LS may extend in the first direction DR1. The linear scale LS may detect (or measure) information such as a position, a moving distance, a moving speed, or the like of the linear motor LM. For example, the linear scale LS may provide the feedback information.

Each of the horizontal air bearing HAB and the vertical air bearing VAB may be disposed on a surface of the moving frame MF. For example, the horizontal air bearing HAB may be disposed on a lower surface of the moving frame MF, and the vertical air bearing VAB may be disposed on a side surface of the moving frame MF. Each of the horizontal air bearing HAB and the vertical air bearing VAB may be fixed (or attached) to the moving frame MF.

For example, each of the horizontal air bearing HAB and the vertical air bearing VAB may be accommodated in the space of the base plate BS. For example, the horizontal air bearing HAB may be disposed between an upper surface (e.g., inner upper surface) of the base plate BS and the lower surface of the moving frame MF, and the vertical air bearing VAB may be disposed between a side surface (e.g., inner side surface) of the base plate BS and the side surface of the moving frame MF.

Although FIGS. 1 and 2 illustrate that the stage 10 includes four horizontal air bearings HAB and four vertical air bearings VAB, embodiments are not limited thereto. In another embodiment, the stage 10 may include three or less or five or more horizontal air bearings HAB or three or less or five or more vertical air bearings VAB.

The error compensation portion CP may be disposed between the base plate BS and the moving frame MF. The error compensation portion CP may be accommodated in the space of the base plate BS. In an embodiment, the error compensation portion CP may be disposed between the upper surface of the base plate BS and the lower surface of the moving frame MF.

The error compensation portion CP may include a guide rail RL and an electromagnet portion EM. The guide rail RL may be disposed on the base plate BS, and may extend in the first direction DR1. The electromagnet portion EM may be disposed on the guide rail RL. In an embodiment, the guide rail RL may be fixed (or attached) to the base plate BS, and the electromagnet portion EM may be fixed (or attached) to the moving frame MF. Detailed descriptions of the error compensation portion CP will be described later.

Although FIGS. 1 and 2 illustrate that the stage 10 includes two error compensation portions CP, and the error compensation portion CP includes two electromagnet portions EM disposed on one guide rail RL, embodiments are not limited thereto. In another embodiment, the stage 10 may include one or more error compensation portions CP, and the error compensation portion CP may include one or more electromagnet portions EM disposed on one or more guide rails RL.

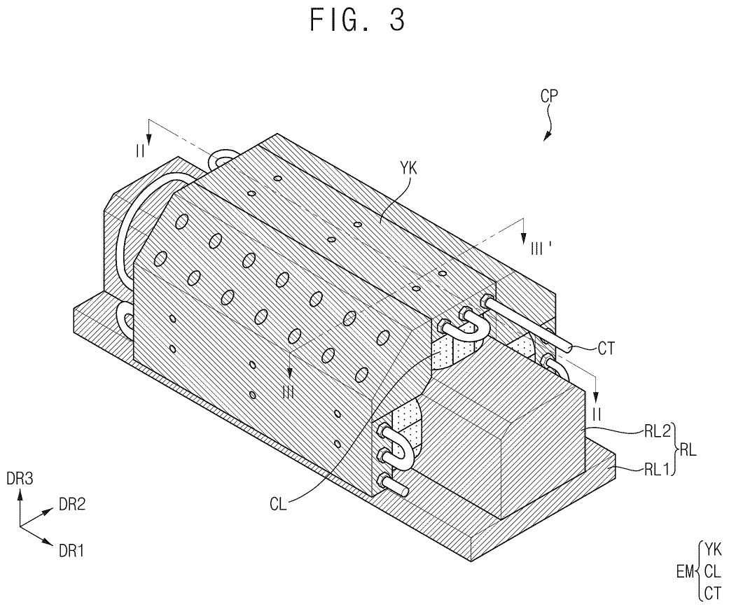

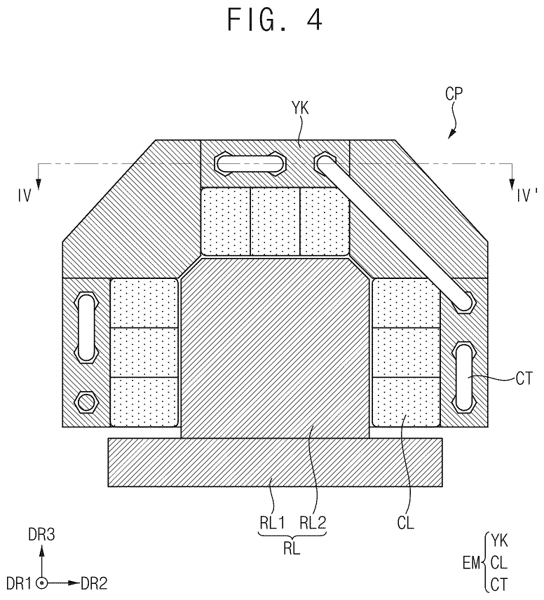

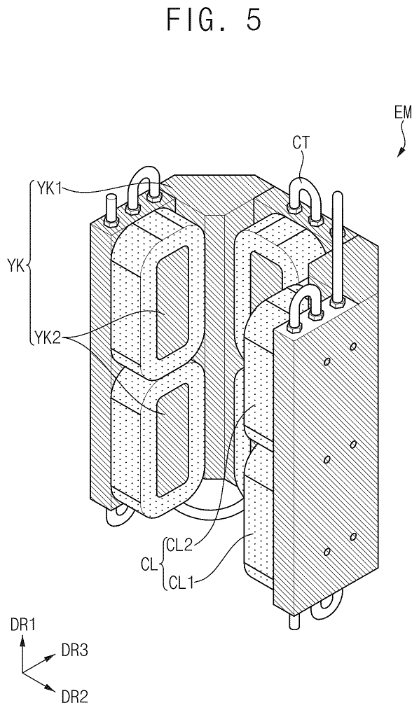

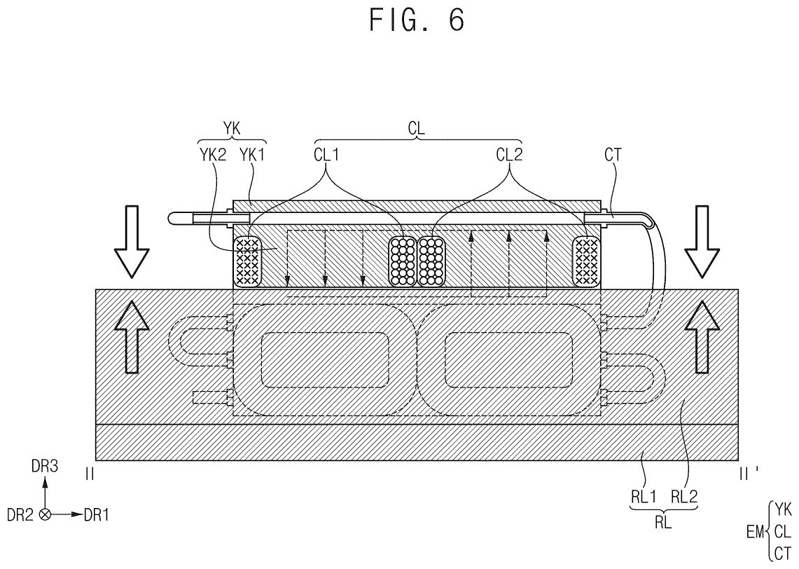

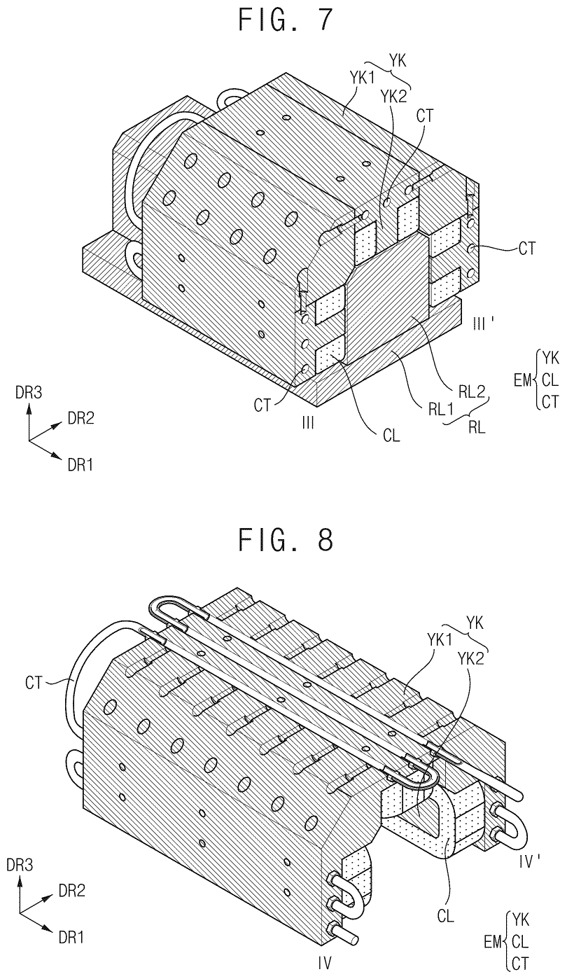

FIG. 3 is a schematic perspective view illustrating an error compensation portion included in the stage of FIG. 1. FIG. 4 is a schematic front view illustrating the error compensation portion of FIG. 3. FIG. 5 is a schematic perspective view illustrating an electromagnet portion included in the error compensation portion of FIG. 3. FIG. 6 is a schematic cross-sectional view taken along line II-II′ of FIG. 3. FIG. 7 is a schematic perspective view taken along line III-III′ of FIG. 3. FIG. 8 is a schematic perspective view taken along line IV-IV′ of FIG. 4.

Referring to FIGS. 2, 3, 4, 5, 6, 7, and 8, the error compensation portion CP may include the guide rail RL and the electromagnet portion EM. In an embodiment, the guide rail RL and the electromagnet portion EM may be spaced apart from each other without contacting each other.

The guide rail RL may extend in the first direction DR1. The guide rail RL may include a material having a relatively high magnetic permeability. For example, the guide rail RL may include iron (Fe). The guide rail RL may include a fixing portion RL1 and a rail portion RL2.

The fixing portion RL1 may be fixed (or attached) to the base plate BS. For example, the guide rail RL may be fixed (or attached) to the base plate BS through the fixing portion RL1. The rail portion RL2 may be disposed on the fixing portion RL1. The rail portion RL2 may protrude from the fixing portion RL1 in the third direction DR3.

In an embodiment, the guide rail RL may have a T-shaped cross-sectional shape. For example, the fixing portion RL1 may protrude further than (or may extend beyond) the rail portion RL2 in the second direction DR2 and a direction opposite to the second direction DR2, and the rail portion RL2 may have a rectangular cross-sectional shape in which edge portions (e.g., opposite edge portions) of an upper surface are chamfered. In another embodiment, the guide rail RL may have a rectangular cross-sectional shape. In still another embodiment, the guide rail RL may have a triangular cross-sectional shape. However, embodiments are not limited thereto, and shape and size of each of the fixing portion RL1 and the rail portion RL2 may be variously changed, and accordingly, shape and size of the guide rail RL may be variously changed.

The electromagnet portion EM may be disposed on the guide rail RL. The electromagnet portion EM may cover at least a portion of the guide rail RL.

In an embodiment, the electromagnet portion EM may cover an upper surface and side surfaces of the rail portion RL2. For example, the electromagnet portion EM may have a U-shaped cross-sectional shape. In another embodiment, the electromagnet portion EM may cover the upper surface and one of the side surfaces of the rail portion RL2. For example, the electromagnet portion EM may have an L-shaped cross-sectional shape. In still another embodiment, the electromagnet portion EM may be disposed on the upper surface of the rail portion RL2. For example, the electromagnet portion EM may have an I-shaped cross-sectional shape. However, embodiments are not limited thereto, and an area of the guide rail RL covered by the electromagnet portion EM may be variously changed according to a shape or the like of the rail portion RL2.

The electromagnet portion EM may be movable in the first direction DR1 or in the direction opposite to the first direction DR1 along the guide rail RL. For example, the electromagnet portion EM may linearly move along the guide rail RL while covering the upper surface and the side surfaces of the rail portion RL2. The electromagnet portion EM may include a coil CL, a yoke YK, and a cooling line CT.

The coil CL may be disposed on the rail portion RL2. A current may be applied to the coil CL. The coil CL may be disposed on at least one surface of the rail portion RL2. For example, one coil CL may be disposed on one surface of the rail portion RL2.

In an embodiment, each of the coils CL may be disposed on the upper surface and the side surfaces of the rail portion RL2. In another embodiment, each of the coils CL may be disposed on the upper surface and one of the side surfaces of the rail portion RL2. In still another embodiment, the coil CL may be disposed on only the upper surface of the rail portion RL2. However, embodiments are not limited thereto, and an area on the rail portion RL2 in which the coil CL is disposed may be variously changed according to a shape or the like of the rail portion RL2.

The coil CL may include a first coil CL1 and a second coil CL2. The second coil CL2 may be adjacent to the first coil CL1 in the first direction DR1. In an embodiment, the first coil CL1 and the second coil CL2 may be wound in opposite directions. For example, the first coil CL1 may be wound in a clockwise direction, and the second coil CL2 may be wound in a counterclockwise direction.

The yoke YK may be disposed on the rail portion RL2 and the coil CL. The yoke YK may cover the coil CL. The yoke YK may include a material having a relatively high magnetic permeability. For example, the yoke YK may include iron. The yoke YK may include a cover portion YK1 and an iron core portion YK2.

The cover portion YK1 may cover the coil CL. For example, the cover portion YK1 may cover an upper surface and side surfaces of the coil CL.

The iron core portion YK2 may protrude from the cover portion YK1 in a direction toward the guide rail RL. For example, the iron core portion YK2 may have a cylindrical shape.

For example, in case that the cover portion YK1 covers the coil CL disposed on the upper surface of the rail portion RL2, the iron core portion YK2 may protrude from the cover portion YK1 toward the upper surface of the rail portion RL2. For another example, in case that the cover portion YK1 covers the coil CL disposed on the side surface of the rail portion RL2, the iron core portion YK2 may protrude from the cover portion YK1 toward the side surface of the rail portion RL2.

In an embodiment, the coil CL may be wound around the iron core portion YK2. For example, the coil CL may surround the iron core portion YK2. The first coil CL1 and the second coil CL2 may be wound around different iron core portions YK2, respectively. For example, the first coil CL1 may surround the iron core portion YK2 in the clockwise direction, and the second coil CL2 may surround the iron core portion YK2 in the counterclockwise direction.

Since the first coil CL1 and the second coil CL2 may be wound in opposite directions, in case that a current is applied to each of the first coil CL1 and the second coil CL2, magnetic fluxes in opposite directions may be generated by the first coil CL1 and the second coil CL2, respectively. For example, in case that the coil CL is disposed on the upper surface of the rail portion RL2, a magnetic flux in a direction opposite to the third direction DR3 may be generated by the first coil CL1, and a magnetic flux in the third direction DR3 may be generated by the second coil CL2.

For example, the electromagnet portion EM and the guide rail RL may be spaced apart from each other, but a distance between the electromagnet portion EM and the guide rail RL may be relatively small. For example, the electromagnet portion EM and the guide rail RL may be spaced apart from each other by a distance ranging from tens to hundreds of micrometers (μm).

For example, since each of the yoke YK and the guide rail RL may include a material having a relatively high magnetic permeability, the magnetic flux generated by the coil CL may be circulated along the yoke YK and the guide rail RL without loss. For example, in case that a current is applied to the coil CL, a large attractive force may be generated between the electromagnet portion EM and the guide rail RL because a density of the magnetic flux circulating through the yoke YK and the guide rail RL is high (see FIG. 6).

The cooling line CT may be disposed on the coil CL. The cooling line CT may be disposed adjacent to the coil CL. In an embodiment, the cooling line CT may penetrate the yoke YK. For example, the cooling line CT may penetrate the cover portion YK1 in the first direction DR1. Coolant may flow into the cooling line CT. The coolant may circulate inside the yoke YK through the cooling line CT.

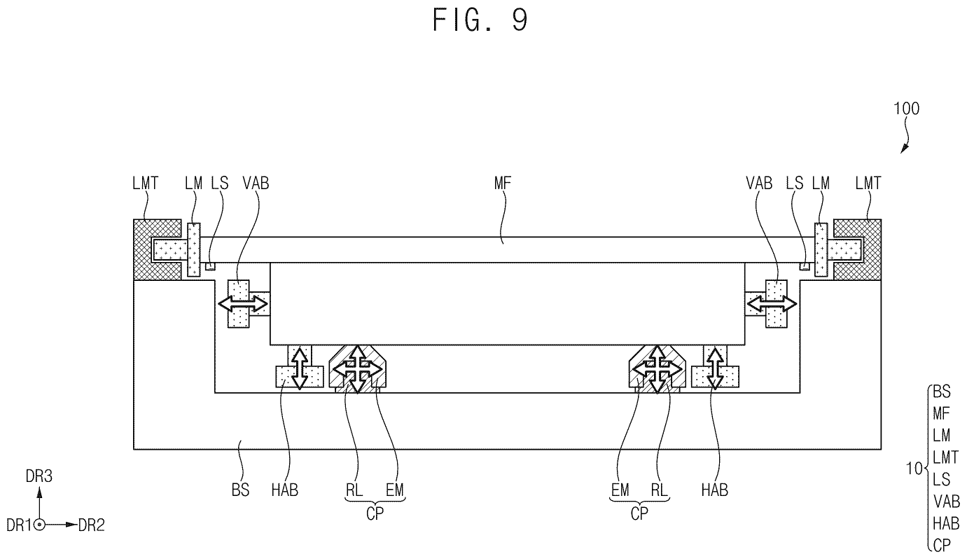

FIG. 9 is a schematic view illustrating an error compensation system according to an embodiment.

For example, the descriptions of an error compensation system 100, as described with reference to FIG. 9, may be referred to as the descriptions of the stage 10, as described with reference to FIGS. 1, 2, 3, 4, 5, 6, 7, and 8. Hereinafter, redundant descriptions will be omitted or simplified for descriptive convenience.

Referring to FIGS. 6 and 9, the error compensation system 100 may include the stage 10. The stage 10 may include the base plate BS, the moving frame MF, the linear motor LM, the linear motor track LMT, the linear scale LS, the horizontal air bearing HAB, the vertical air bearing VAB, and the error compensation portion CP.

Each of the horizontal air bearing HAB and the vertical air bearing VAB may be fixed (or attached) to the moving frame MF. In an embodiment, each of the horizontal air bearing HAB and the vertical air bearing VAB may float (or hover) the moving frame MF from the base plate BS by discharging air. For example, each of the horizontal air bearing HAB and the vertical air bearing VAB may discharge air toward the base plate BS to separate the moving frame MF from the base plate BS.

In case that the moving frame MF linearly moves along an axis parallel to the first direction DR1, a translational motion error (e.g., flatness error or straightness error) and a rotational motion error (e.g., roll error, pitch error, or yaw error) may occur along axes parallel to each of the first, second, and third directions DR1, DR2, and DR3. In an embodiment, the error compensation system 100 may compensate for the motion error through the error compensation portion CP.

The linear scale LS may be disposed below the moving frame MF. The linear scale LS may detect and provide feedback information such as a position of the moving frame MF or the like. For example, the linear scale LS may detect and provide feedback information such as the translational motion error that occurs in the moving frame MF along the axis parallel to the first direction DR1.

The error compensation system 100 may further include an interferometer. The interferometer may detect and provide feedback information such as the position of the moving frame MF or the like. For example, the interferometer may detect and provide feedback information such as the translational motion error and the rotational motion error that occur in the moving frame MF along the axes parallel to each of the first, second, and third directions DR1, DR2, and DR3.

In an embodiment, the error compensation system 100 may control the error compensation portion CP according to an error value provided by the linear scale LS and an error value provided by the interferometer. For example, the current applied to the error compensation portion CP may be controlled to compensate for the error. For example, the current applied to the coil CL of the error compensation portion CP may be controlled to compensate for the error.

In case that the current applied to the coil CL increases, the attractive force between the electromagnet portion EM and the guide rail RL may increase, and the distance between the electromagnet portion EM and the guide rail RL may decrease. In case that the current applied to the coil CL decreases, the attractive force between the electromagnet portion EM and the guide rail RL may decrease, and the distance between the electromagnet portion EM and the guide rail RL may increase. For example, the error compensation system 100 may compensate for the error with respect to linear motion of the stage 10 by controlling a magnitude of the current applied to the coil CL included in the error compensation portion CP to control the attractive force between the electromagnet portion EM and the guide rail RL.

For example, in case that an error occurs, such as the moving frame MF being biased in a straight direction (i.e., the first direction DR1 or the direction opposite to the first direction DR1), a horizontal direction (i.e., the second direction DR2 or a direction opposite to the second direction DR2), or a vertical direction (i.e., the third direction DR3 or the direction opposite to the third direction DR3), the moving frame MF rotating around the axes parallel to each of the first, second, and third directions DR1, DR2, and DR3, or the like, the error compensation system 100 may compensate for the error by adjusting the current applied to the coil CL.

For example, since the error compensation portion CP may be disposed between the upper surface of the base plate BS and the lower surface of the moving frame MF, in case that an error such as the moving frame MF being biased in the straight or vertical direction, the moving frame MF rotating around the axes parallel to each of the first and second directions DR1 and DR2, or the like occurs, the error may be more effectively compensated.

For example, since the current for generating the magnetic flux is applied to the coil CL, heat may be generated from the coil CL. In an embodiment, the error compensation system 100 may flow the coolant into the cooling line CT of the error compensation portion CP. Since the coolant may be circulated through the cooling line CT, the heat generated from the coil CL may be effectively released while compensating for the error.

The error compensation system 100 according to an embodiment may include the stage 10 including the error compensation portion CP. The error compensation portion CP may include the guide rail RL and the electromagnet portion EM. In case that a linear motion error occurs in the stage 10, the error may be compensated by controlling the current applied to the coil CL of the electromagnet portion EM. For example, the heat generated from the coil CL may be released by flowing the coolant into the cooling line CT of the electromagnet portion EM. Therefore, since the linear motion error with respect to multi-axis may be precisely compensated, the stage 10 with improved reliability may be implemented.

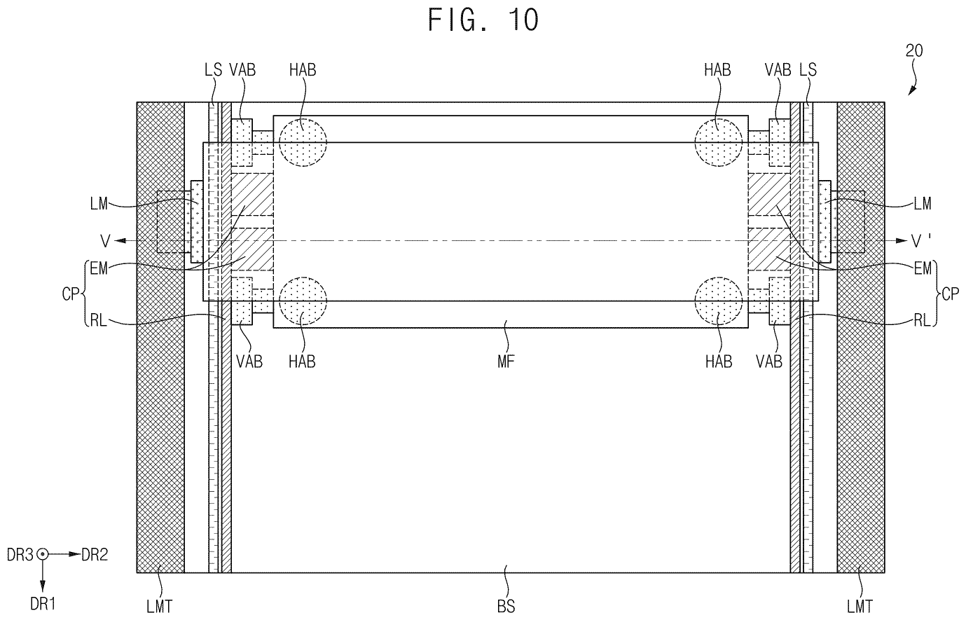

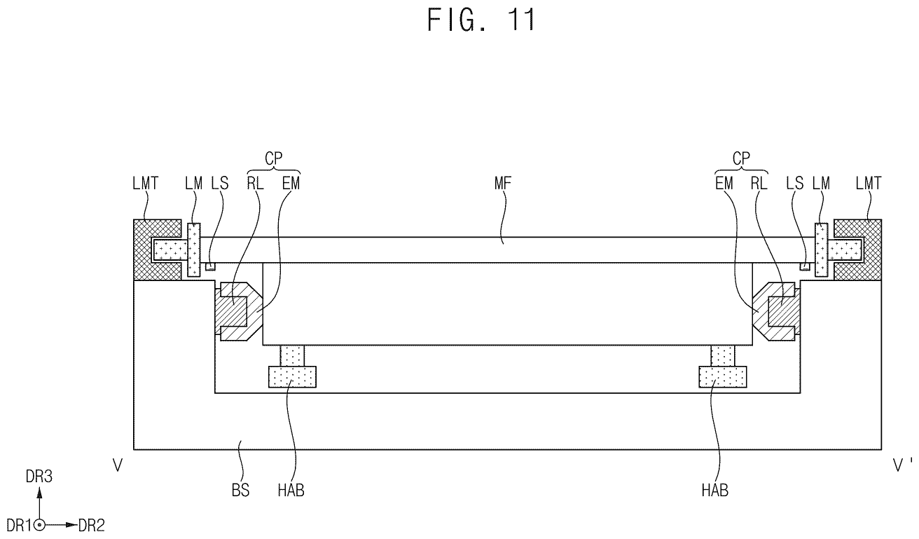

FIG. 10 is a schematic plan view illustrating a stage according to another embodiment. FIG. 11 is a schematic cross-sectional view taken along line V-V′ of FIG. 10.

A stage 20 described with reference to FIGS. 10 and 11 may be substantially the same as or similar to the stage 10 described with reference to FIGS. 1, 2, 3, 4, 5, 6, 7, and 8 except for an arrangement of the error compensation portion CP. Hereinafter, redundant descriptions will be omitted or simplified for descriptive convenience.

Referring to FIGS. 10 and 11, the stage 20 may include a base plate BS, a moving frame MF, a linear motor LM, a linear motor track LMT, a linear scale LS, a horizontal air bearing HAB, a vertical air bearing VAB, and an error compensation portion CP.

The moving frame MF may be disposed on the base plate BS. The moving frame MF may be spaced apart from the base plate BS in a third direction DR3. The moving frame MF may be movable in a first direction DR1 or in a direction opposite to the first direction DR1.

The linear motor LM may be disposed on a surface of the moving frame MF, and the linear motor track LMT may be disposed on the base plate BS. For example, the linear motor LM may include a coil, and the linear motor track LMT may include a magnet. The linear motor LM and the linear motor track LMT may not be in contact with each other.

The linear motor LM may be movable in the first direction DR1 or in the direction opposite to the first direction DR1 along the linear motor track LMT. The moving frame MF may linearly move by the linear motor LM and the linear motor track LMT.

The linear scale LS may be disposed on the base plate BS. The linear scale LS may detect and provide feedback information such as a position, a moving distance, a moving speed, or the like of the linear motor LM.

Each of the horizontal air bearing HAB and the vertical air bearing VAB may be disposed on a surface of the moving frame MF. For example, the horizontal air bearing HAB may be disposed on a lower surface of the moving frame MF, and the vertical air bearing VAB may be disposed on a side surface of the moving frame MF.

The error compensation portion CP may be disposed between the base plate BS and the moving frame MF. In an embodiment, the error compensation portion CP may be disposed between a side surface of the base plate BS and the side surface of the moving frame MF.

The error compensation portion CP may include a guide rail RL and an electromagnet portion EM. The guide rail RL may be disposed on the base plate BS, and the electromagnet portion EM may be disposed on the guide rail RL. In an embodiment, the guide rail RL may be fixed (or attached) to the base plate BS, and the electromagnet portion EM may be fixed (or attached) to the moving frame MF. The guide rail RL and the electromagnet portion EM may not be in contact with each other, and may be spaced apart from each other.

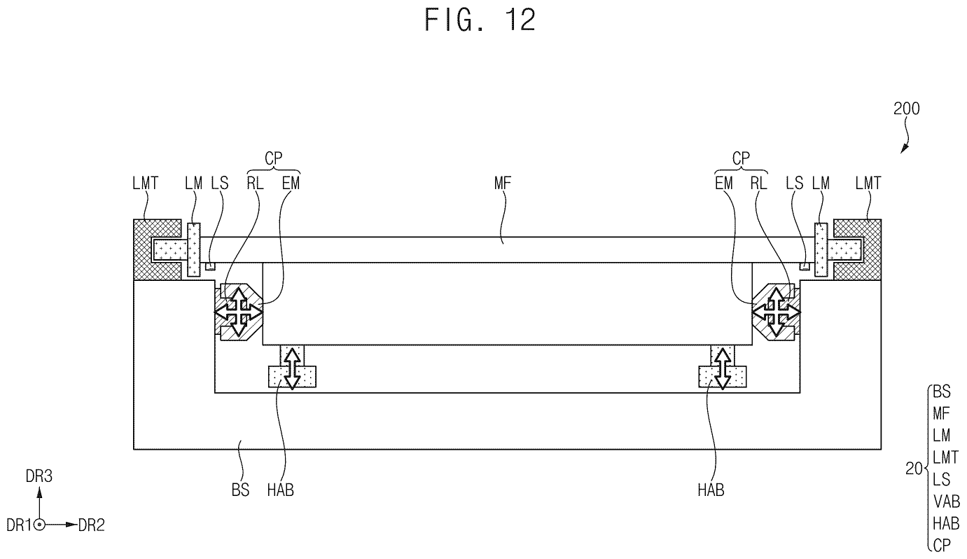

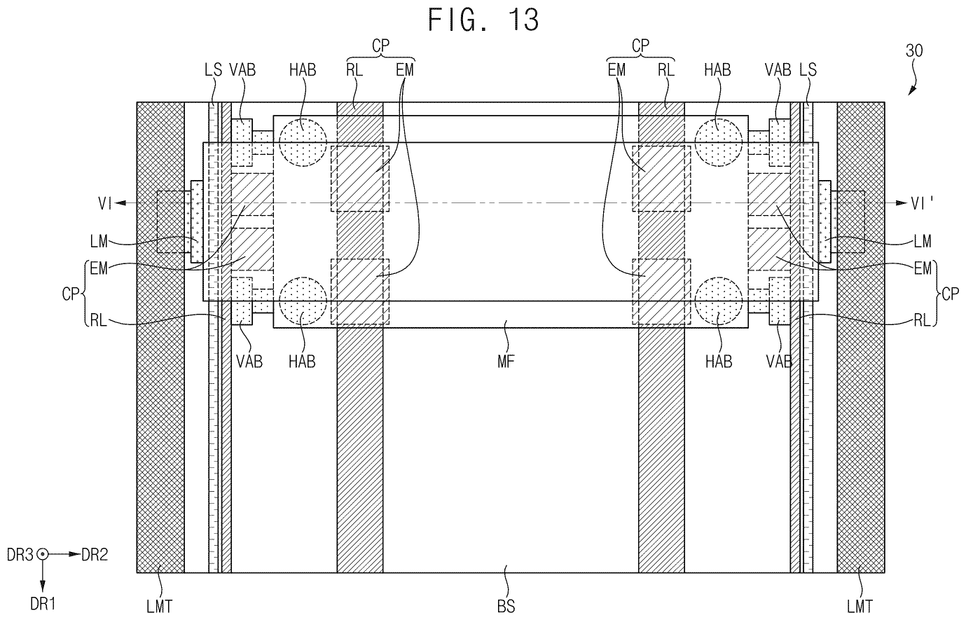

FIG. 12 is a schematic view illustrating an error compensation system according to another embodiment.

For example, an error compensation system 200 described with reference to FIG. 12 may use the stage 20 described with reference to FIGS. 10 and 11. For example, the error compensation system 200 described with reference to FIG. 12 may be substantially the same as or similar to the error compensation system 100 described with reference to FIG. 9 except for an arrangement of the error compensation portion CP. Hereinafter, redundant descriptions will be omitted or simplified for descriptive convenience.

Referring to FIGS. 10, 11, and 12, the error compensation system 200 may include the stage 20. The stage 20 may include the base plate BS, the moving frame MF, the linear motor LM, the linear motor track LMT, the linear scale LS, the horizontal air bearing HAB, the vertical air bearing VAB, the error compensation portion CP, and an interferometer.

The error compensation system 200 may float (or hover) the moving frame MF from the base plate BS through the horizontal air bearing HAB and the vertical air bearing VAB, respectively. The error compensation system 200 may compensate for a linear motion error of the moving frame MF through the error compensation portion CP.

The linear scale LS may detect and provide feedback information such as a translational motion error that occurs in the moving frame MF along an axis parallel to the first direction DR1. The interferometer may detect and provide feedback information such as a translational motion error and a rotational motion error that occur in the moving frame MF along axes parallel to each of first, second, and third directions DR1, DR2, and DR3.

In an embodiment, the error compensation system 200 may control the error compensation portion CP according to an error value provided by the linear scale LS and an error value provided by the interferometer. For example, a magnitude of a current applied to the electromagnet portion EM of the error compensation portion CP may be controlled to compensate for the error. For example, in case that an error occurs, such as the moving frame MF being biased in a straight, vertical, or horizontal direction, the moving frame MF rotating around the axes parallel to each of the first, second, and third directions DR1, DR2, and DR3, or the like, the error compensation system 200 may compensate for the error by adjusting the current applied to the electromagnet portion EM.

Since the error compensation portion CP may be disposed between the side surface of the base plate BS and the side surface of the moving frame MF, in case that an error such as the moving frame MF being biased in the straight or horizontal direction, the moving frame MF rotating around the axis parallel to the third direction DR3, or the like occurs, the error may be more effectively compensated.

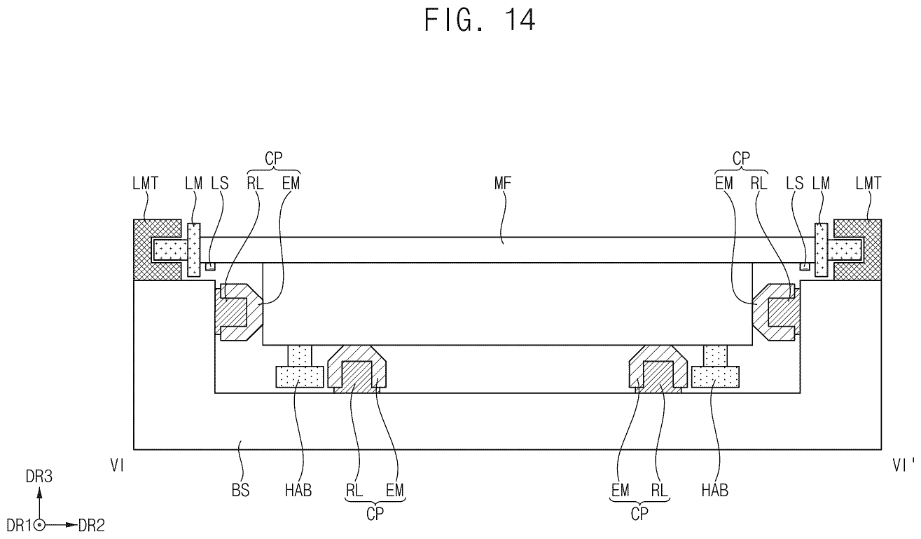

FIG. 13 is a schematic plan view illustrating a stage according to still another embodiment. FIG. 14 is a schematic cross-sectional view taken along line VI-VI′ of FIG. 13.

A stage 30 described with reference to FIGS. 13 and 14 may be substantially the same as or similar to the stage 10 described with reference to FIGS. 1, 2, 3, 4, 5, 6, 7, and 8 except for an arrangement of the error compensation portion CP. Hereinafter, redundant descriptions will be omitted or simplified for descriptive convenience.

Referring to FIGS. 13 and 14, the stage 30 may include a base plate BS, a moving frame MF, a linear motor LM, a linear motor track LMT, a linear scale LS, a horizontal air bearing HAB, a vertical air bearing VAB, and an error compensation portion CP.

The moving frame MF may be disposed on the base plate BS. The moving frame MF may be spaced apart from the base plate BS in a third direction DR3. The moving frame MF may be movable in a first direction DR1 or in a direction opposite to the first direction DR1.

The linear motor LM may be disposed on a surface of the moving frame MF, and the linear motor track LMT may be disposed on the base plate BS. For example, the linear motor LM may include a coil, and the linear motor track LMT may include a magnet. The linear motor LM and the linear motor track LMT may not be in contact with each other.

The linear motor LM may be movable in the first direction DR1 or in the direction opposite to the first direction DR1 along the linear motor track LMT. The moving frame MF may linearly move by the linear motor LM and the linear motor track LMT.

The linear scale LS may be disposed on the base plate BS. The linear scale LS may detect and provide feedback information such as a position, a moving distance, a moving speed, or the like of the linear motor LM.

Each of the horizontal air bearing HAB and the vertical air bearing VAB may be disposed on a surface of the moving frame MF. For example, the horizontal air bearing HAB may be disposed on a lower surface of the moving frame MF, and the vertical air bearing VAB may be disposed on a side surface of the moving frame MF.

The error compensation portion CP may be disposed between the base plate BS and the moving frame MF. In an embodiment, the error compensation portion CP may be disposed between an upper surface of the base plate BS and the lower surface of the moving frame MF, and between a side surface of the base plate BS and the side surface of the moving frame MF.

The error compensation portion CP may include a guide rail RL and an electromagnet portion EM. The guide rail RL may be disposed on the base plate BS, and the electromagnet portion EM may be disposed on the guide rail RL. In an embodiment, the guide rail RL may be fixed (or attached) to the base plate BS, and the electromagnet portion EM may be fixed (or attached) to the moving frame MF. The guide rail RL and the electromagnet portion EM may not be in contact with each other, and may be spaced apart from each other.

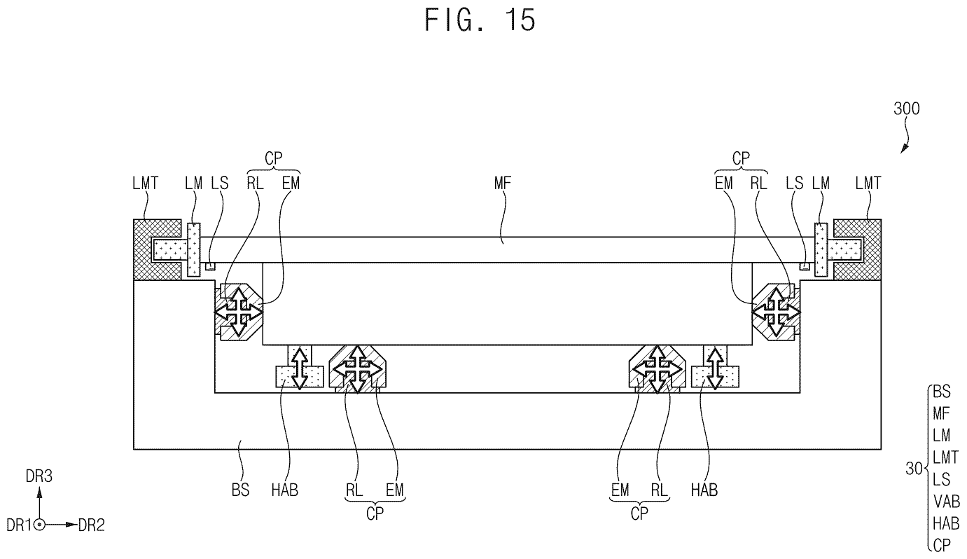

FIG. 15 is a schematic view illustrating an error compensation system according to still another embodiment.

For example, an error compensation system 300 described with reference to FIG. 15 may use the stage 30 described with reference to FIGS. 13 and 14. For example, the error compensation system 300 described with reference to FIG. 15 may be substantially the same as or similar to the error compensation system 100 described with reference to FIG. 9 except for an arrangement of the error compensation portion CP. Hereinafter, redundant descriptions will be omitted or simplified for descriptive convenience.

Referring to FIGS. 13, 14, and 15, the error compensation system 300 may include the stage 30. The stage 30 may include the base plate BS, the moving frame MF, the linear motor LM, the linear motor track LMT, the linear scale LS, the horizontal air bearing HAB, the vertical air bearing VAB, the error compensation portion CP, and an interferometer.

The error compensation system 300 may float (or hover) the moving frame MF from the base plate BS through the horizontal air bearing HAB and the vertical air bearing VAB, respectively. The error compensation system 300 may compensate for a linear motion error of the moving frame MF through the error compensation portion CP.

The linear scale LS may detect and provide feedback information such as a translational motion error that occurs in the moving frame MF along an axis parallel to the first direction DR1. The interferometer may detect and provide feedback information such as a translational motion error and a rotational motion error that occur in the moving frame MF along axes parallel to each of first, second, and third directions DR1, DR2, and DR3.

In an embodiment, the error compensation system 300 may control the error compensation portion CP according to an error value provided by the linear scale LS and an error value provided by the interferometer. For example, a magnitude of a current applied to the electromagnet portion EM of the error compensation portion CP may be controlled to compensate for the error. For example, in case that an error occurs, such as the moving frame MF being biased in a straight, vertical, or horizontal direction, the moving frame MF rotating around axes parallel to each of the first, second, and third directions DR1, DR2, and DR3, or the like, the error compensation system 300 may compensate for the error by adjusting the current applied to the electromagnet portion EM.

Since the error compensation portion CP may be disposed between the upper surface of the base plate BS and the lower surface of the moving frame MF, and between the side surface of the base plate BS and the side surface of the moving frame MF, the motion error that may occur in the stage 30 may be more effectively compensated.

The embodiments may be applied to a manufacturing process of various display devices. For example, the embodiments may be applicable to a manufacturing process of various display devices such as display devices for vehicles, ships and aircraft, portable communication devices, display devices for exhibition or information transmission, medical display devices, and the like.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A stage comprising:
a base plate extending in a first direction and a second direction intersecting the first direction;
a moving frame disposed on the base plate and movable in the first direction or in a direction opposite to the first direction; and
an error compensation portion disposed between the base plate and the moving frame, the error compensation portion including:
a guide rail extending in the first direction; and
an electromagnet portion disposed on the guide rail and covering at least a portion of the guide rail.

2. The stage of claim 1, wherein the electromagnet portion includes:
a coil disposed on at least one surface of the guide rail; and
a yoke covering the coil.

3. The stage of claim 2, wherein the coil includes:
a first coil; and
a second coil adjacent to the first coil in the first direction and wound in a direction opposite to a direction in which the first coil is wound.

4. The stage of claim 2, wherein the yoke includes:
a cover portion covering the coil; and
an iron core portion protruding in a direction toward the guide rail.

5. The stage of claim 4, wherein the coil is wound around the iron core portion.

6. The stage of claim 2, wherein the electromagnet portion further includes a cooling line passing through the yoke.

7. The stage of claim 1, wherein the guide rail and the electromagnet portion are spaced apart from each other.

8. The stage of claim 1, further comprising:
an air bearing disposed on at least one surface of the moving frame.

9. The stage of claim 1, further comprising:
a linear motor fixed to the moving frame and movable in the first direction or in the direction opposite to the first direction,
wherein the moving frame is movable by the linear motor.

10. The stage of claim 1, wherein
the guide rail is fixed to the base plate, and
the electromagnet portion is fixed to the moving frame.

11. The stage of claim 1, wherein the error compensation portion is disposed on an upper surface of the base plate.

12. The stage of claim 1, wherein the error compensation portion is disposed on a side surface of the base plate.

13. An error compensation system comprising:
a stage,
wherein the stage includes:
a base plate extending in a first direction and a second direction intersecting the first direction;
a moving frame disposed on the base plate and movable in the first direction or in a direction opposite to the first direction; and
an error compensation portion disposed between the base plate and the moving frame, the error compensation portion including:
a guide rail extending in the first direction; and
an electromagnet portion disposed on the guide rail and covering at least a portion of the guide rail.

14. The error compensation system of claim 13, wherein the electromagnet portion includes:
a coil disposed on at least one surface of the guide rail and to which a current is applied;
a yoke covering the coil; and
a cooling line passing through the yoke.

15. The error compensation system of claim 14, wherein the coil includes:
a first coil wound in a direction; and
a second coil adjacent to the first coil in the first direction and wound in a direction opposite to the direction.

16. The error compensation system of claim 14, wherein the yoke includes:
a cover portion covering the coil; and
an iron core portion protruding in a direction toward the guide rail and around which the coil is wound.

17. The error compensation system of claim 14, wherein a motion error of the moving frame is compensated by controlling the current applied to the coil.

18. The error compensation system of claim 14, wherein
an attractive force is generated between the guide rail and the electromagnet portion by the current applied to the coil, and
a magnitude of the attractive force is adjusted by controlling a magnitude of the current applied to the coil.

19. The error compensation system of claim 14, wherein heat generated from the coil is released by flowing coolant into the cooling line.

20. The error compensation system of claim 13, wherein the guide rail and the electromagnet portion are spaced apart from each other.
